(19) United States
(12) Patent Application Publication
(10) Pub. No.: US 2008/0204053 A1
(43) Pub. Date: Aug. 28, 2008

(54) CONTROL CIRCUIT FOR CLOCKED CONTROL OF AT LEAST ONE LIGHT EMITTING DIODE

(75) Inventor: Klaus-Dieter Grebner, Markt Rodach (DE)

Correspondence Address: BROOKS KUSHMAN P.C. / LEAR CORPORATION, 1000 TOWN CENTER, TWENTY-SECOND FLOOR, SOUTHFIELD, MI, 48075-1238, US

(73) Assignee: LEAR CORPORATION, Southfield, MI (US)

(21) Appl. No.: 12/035,738

(22) Filed: Feb. 22, 2008

(30) Foreign Application Priority Data
Feb. 24, 2007 (DE) 10 2007 009 104.6

(51) Int. Cl. G01R 27/00

(52) U.S. Cl. 324/706

(57) ABSTRACT

A control circuit includes a clock pulse generator operable to output a pulse-frequency ratio to a constant voltage source in order to control the power output of the constant voltage source. The control circuit further includes a driver circuit for the clocked control of at least one light emitting diode (LED) to which a measurement resistor is connected in parallel. The LED is supplied with power by the constant voltage source. The LED is turned on when the power is greater than a forward power level and is turned off when the power is less than the forward power level. The driver circuit taps a measurement voltage of the measurement resistor while the LED is supplied with power less than the forward power level. The clock pulse generator varies the pulse-frequency ratio as a function of the measurement voltage of the measurement resistor.

### CROSS-REFERENCE TO RELATED APPLICATIONS

This application claims foreign priority benefits under 35 U.S.C. § 119(a)-(d) to DE 10 2007 009 104.6, filed Feb. 24, 2007, which is hereby incorporated by reference in its entirety.

### BACKGROUND OF THE INVENTION

1. Field of the Invention

The present invention relates to a control circuit having a clock pulse generator and a driver circuit for the clocked control of a light emitting diode(s) (LED(s)) in which the control circuit varies the pulse-frequency ratio of a power source of the LED(s) as a function of a measurement voltage tapped from a measurement resistor connected in parallel to the LED(s).

2. Background Art

DE 101 08 132 A1 describes a driver circuit for driving a voltage-sensitive load such as a light emitting diode(s) (LED(s)) from a remote control unit. A controllable current source and a control element having a first input at a prescribed reference voltage and a second input for routing the control voltage are provided for the load in order to evaluate status signals.

An LED has a current-voltage characteristic similar to that of a Zener diode. An LED emits no light as no current flows in the LED while the supply voltage to the LED is less than a predetermined voltage. Once the supply voltage exceeds the predetermined voltage, the current increases abruptly and the LED begins to emit light. Typically, an LED (or a group of LEDs connected in series) is driven through a protective resistor which sets the current through the LED(s) for a specific supply voltage. The current through the LED(s) remains constant as long as the supply voltage remains constant.

The supply voltage provided by a power supply such as an on-board vehicle power supply may fluctuate. For instance, the supply voltage of a 12 volts (nominal voltage) vehicle power supply may fluctuate between 9 and 16 volts. If the vehicle has an external power supply, the supply voltage can reach 32 volts in exceptional situations. Thus, as long as only one protective resistor is connected in series with the LED(s), the LED(s) will experience unacceptable brightness fluctuations due to fluctuations in the supply voltage. This can also result in the destruction of the LED(s) when driven, for efficiency reasons, by a nominal voltage of 12 volts which is near maximum load. At higher operating voltages (i.e., nominal voltages) of an on-board power supply the same relationships are satisfied.

In known circuits, the current supply for an LED(s) is achieved by constant current controllers (as described in DE 101 08 132 A1) or by variable and adjustable voltage regulators. DE 101 08 132 A1 also describes the insertion of an ohmic resistance connected in parallel to a group of LEDs connected in series. An object of the second constant current source is to switch the LEDs into a transmission mode by connecting to a test line through a transistor and a resistor, and to apply a low-value measurement current to the LEDs in the cutoff state of a main switch that is not quite sufficient to cause the LEDs to light but is capable of producing a sufficient voltage drop over the ohmic resistance so that it can be detected on the status line and evaluated. No current flows through the LEDs in the open-load failure situation. As a direct consequence, a significantly smaller current flows the supply line and the ohmic resistance whereby the potential at the output of the resistor connected to the test line is raised. An error pulse in the open-load failure situation thus results in the neighborhood of the reference voltage, e.g., 5 volts. For an intact load, an average level appears and the test signal is a simple square wave between 0 and 5 volts.

### SUMMARY OF THE INVENTION

An object of the present invention includes a control system for a light emitting diode(s) (LED) that assures a constant brightness of the LED(s) even during voltage fluctuations of a supply voltage source.

In carrying out the above object and other objects, the present invention provides a control circuit having a clock pulse generator and a driver circuit. The clock pulse generator is operable to output a pulse-frequency ratio to a constant voltage source in order to control the power output of the constant voltage source. The driver circuit is for the clocked control of at least one light emitting diode (LED) to which a measurement resistor is connected in parallel. The LED is supplied with power by the constant voltage source. The LED is turned on when the power is greater than a forward power level and is turned off when the power is less than the forward power level. The driver circuit taps a measurement voltage of the measurement resistor while the LED is supplied with power less than the forward power level. The clock pulse generator varies the pulse-frequency ratio as a function of the measurement voltage of the measurement resistor.

Further, in carrying out the above object and other objects, the present invention provides a control system for a LED branch having at least one LED and a measurement resistor connected in parallel to the LED branch in which the LED branch is supplied with power by a constant voltage source such that the at least one LED is turned on when the power is greater than a forward power level and is turned off when the power is less than the forward power level. The control system includes a control circuit operable for controlling the constant voltage source to supply power to the LED branch greater than the forward power level and less than the forward power level. The control circuit includes a series resistor connectable in series with the measurement resistor to form a measurement bridge. The control circuit causes the series resistor to connect in series with the measurement resistor to form the measurement bridge while controlling the constant voltage source to supply power to the LED branch less than the forward power level such that the at least one LED of the LED branch is turned off. The control circuit taps a measurement value of the measurement resistor while the measurement bridge is formed. The control system further includes an evaluation circuit operable to adjust the constant voltage source to a specific forward voltage and adjust a pulse-frequency ratio for the constant voltage source as a function of the measurement voltage such that the light intensity of the LED is constant.

As described above in the Background Art section, the current supply for an LED(s) is achieved by a constant current source in known circuits. In accordance with embodiments of the present invention, the power supply for an LED(s) is a constant voltage source in which the current can vary. As such, an LED (or a group of LEDs connected in series) or LEDs connected in parallel are connected with a constant voltage source while the current can vary. The constant voltage source may be switchable (e.g., adjustable or reversible).

The use of a constant voltage source as the power supply has an advantage that parallel branches of LED(s) can be supplied from one power supply source and the LED branches can be switched on and off independently of one another. The output voltage thereby remains constant.

In cases where the constant voltage source is adjustable or reversible, the same constant voltage source may apply the measurement voltage during the blocking phase of the LED(s) to a measurement on a measurement resistor connected in parallel with the LED(s). For this, another resistor (i.e., a series resistor) is connected in series with the measurement resistor while the LED(s) is blocked with the measurement and series resistors forming a measurement bridge of the blocked LED(s) during a defined measurement period. A voltage less than the forward voltage of the LED(s) can be applied by the constant voltage source and a measurement voltage can be tapped from the measurement bridge during the measurement period. Based on the measurement voltage, an evaluation circuit adjusts the constant voltage source to a specific forward voltage and the pulse-frequency ratio of the clock pulse generator such that the light intensity of the LED(s) is approximately constant.

Each individual light such as a rear vehicle light can have a plurality of LEDs to produce a sufficient light intensity such that other nearby vehicle operators see the vehicle light. The LEDs may include one or more LED branches connected in parallel in which each LED branch includes one or more LEDs connected in series. Different lights such as left and right lights are controlled by a remote control. The control circuit may be either integrated in the remote control or located in a light itself. Further, the measurement resistor can span the entire group of LEDs (i.e., one measurement resistor connected in parallel to one LED branch with the other LED branches being void of measurement resistors). Any of the LED branches may have a protective resistor.

The measurement resistor connected in parallel to an LED branch may be an NTC resistor or a thermal resistor. The use of such a resistor type has an advantage that heating may be detected and can be taken into consideration during the pulse width modulation.

The control circuit can be designed so that different lights including combination lights are controllable in this manner.

In order to obtain measurement values for clocked control adjustment, it is thus expedient to provide a parallel resistor with a measurement bridge on an LED branch. This can also be provided by other separately connected individual groups of LEDs. Pulse width modulation of the control pulse for normal operation is then regulated in a well-known manner as a function of the measurement value while the constant voltage source is switched respectively to different voltage values between the normal supply voltage and the measurement function. In order to enable clocked control of the LEDs and the measurement bridge, a switch can be provided in parallel with the series resistor of the respective measurement bridge for the clocked conductive switching as well as such a switch in series with the LED(s) of an LED branch.

In order to achieve uniform brightness of the LEDs, and in particular of LEDs connected in parallel, it is expedient to connect matched or adjustable resistors in series with the LEDs (i.e., protective resistors) and to adjust the protective resistors as a function of the measured light intensities. It is possible to combine selected protective resistors or laser-matchable resistors with the LEDs in a manner similar to as described in DE 100 37 420 A1. Matching of LEDs with different characteristics and colors can also be achieved simply in this manner.

Arranging the measurement resistors in parallel to the LED network enables the separation of control electronics and the LED support without additional wiring expenditure. Separation of the applications allows the flexibility with respect to integration, assembly, space requirements, cable routing, and reusability to be increased by using the control with different LED-arrays. For this reason, the control circuit can be located in the central control unit. However, the control circuit can also be arranged in the immediate neighborhood of the LED(s).

A measurement resistor can be connected in parallel to an individual LED of an LED branch even when the LED branch includes a plurality of LEDs connected in series. The measurement resistors may have variable resistance different from one another. A measurement resistor can bridge (i.e., be connected in parallel to) an LED and a protective resistor of an LED branch having LEDs and the protective resistor connected in series. Likewise, the measurement resistor can bridge the LEDs and the protective resistor of the LED branch. The arrangement and selection of a variable measurement resistor connected in parallel to an LED branch is to take into consideration that the measurement resistor can be measured in a region in which the resistor current is significantly higher than the current in the blocking region of the LEDs of the LED branch. The presence of protective resistors does not represent a fundamental problem, but is necessary to prevent interference. Instead of using a fixed resistor as the measurement resistor, a variable measurement resistor can measure different LED parameters.

The temperature of the LEDs can be detected by using temperature-dependent resistors such as NTCs as the measurement resistors. To do this, the measurement of an LED is switched off briefly and the measurement resistor is measured in the OFF phase. This allows a simple determination of overheating conditions. The surrounding brightness of the LED or LED branches can be measured with the use of light-sensitive resistors as the measurement resistors. An updating of the LED light current can thus also be obtained over the lifetime and/or as a function of the surrounding temperature. If LED arrays are used, only one variable measurement resistor is required for setting the parameter, and then the other measurement resistors can be used for other functions. The switch for controlling the measurement bridge can also be provided in the parallel LED branch. Likewise, different measurement resistors can be connected in parallel, which can be switched differently in order to be able to detect different measurement voltage values from the evaluation circuit in the control circuit.

The above features, and other features and advantages of the present invention are readily apparent from the following detailed descriptions thereof when taken in connection with the accompanying drawings.

### BRIEF DESCRIPTION OF THE DRAWINGS

FIG. 1 illustrates a control circuit for the clocked control of light emitting diodes (LED(s)) in accordance with an embodiment of the present invention; and

FIG. 2 illustrates operating states of the control circuit.

### DETAILED DESCRIPTION OF THE PREFERRED EMBODIMENT(S)

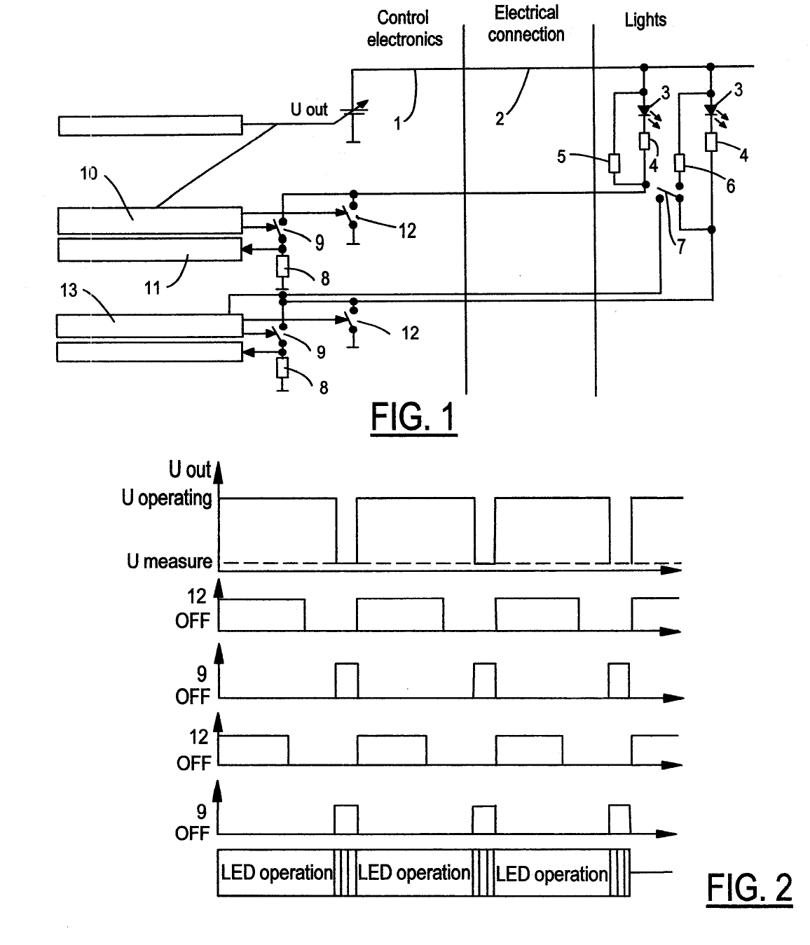

FIG. 1 illustrates a control circuit for the clocked control of light emitting diodes (LED(s)) in accordance with an embodiment of the present invention. An adjustable constant voltage source 1 may be integrated into the control circuit. A lamp or light assembly is remote from voltage source 1. An electrical connection 2 connects voltage source 1 to the light assembly. The light assembly includes first and second LED branches. The first LED branch includes an LED 3 and a protective resistor 4 connected in series. Similarly, the second LED branch includes an LED 3 and, if required, a protective resistor 4 connected in series. The first and second LED branches are connected in parallel to one another. Protective resistors 4 are matched with the same resistance such that LEDs 3 have the same brightness and, thus, light intensity, when LEDs 3 are driven with the same operating current during their illumination phase.

A first measurement resistor 5 is connected in parallel to the first LED branch (i.e., first measurement resistor 5 is connected in parallel to LED 3 and protective resistor 4 of the first LED branch). Similarly, a second measurement resistor 6 is connected in parallel to the second LED branch (i.e., second measurement resistor 6 is connected in parallel to LED 3 and protective resistor 4 (if required) of the second LED branch). An electronic switch 7 is connected in series with second measurement resistor 6 and is connected in parallel to the second LED branch.

A first measurement bridge for the first LED branch includes first measurement resistor 5 (which is connected in parallel to the first LED branch) and a series resistor 8. Resistor 8 is connected in series between an electronic switch 9 and ground. A control circuit 10 can open and close switch 9. When switch 9 is closed while the first LED branch is blocked off (i.e., subject to a supply voltage less than the voltage required for LED 3 of the first LED branch to turn one and emit light), the first measurement bridge for the first LED branch comprising first measurement resistor 5 and resistor 8 is formed. Control circuit 10 switches switch 9 closed during the measurement phase of the first LED branch. As such, control circuit 10 closes switch 9 during the measurement phase which takes place in the blocking region of LED 3. The result of the measurement is tapped from resistor 8 of the first measurement bridge and supplied to an evaluation circuit 11. In turn, evaluation circuit 11 changes the pulse width modulation (PWM) for controlling LED 3 of the first LED branch as a function of the measurement value tapped from resistor 8 of the first measurement bridge. LED 3 of the first LED branch receives its operating current corresponding to the PWM by control circuit 10 simultaneously closing a switch 12 and opening switch 9. (Control circuit 10 opens switch 12 during the measurement phase and closes switch 12 when the operating current flows through LED 3 of the first LED branch.) As described, control circuit 10 and evaluation circuit 11 together include a clock pulse generator and a driver circuit for the clocked control of LED 3 of the first LED branch.

This measurement principle by setting the operating parameter can be carried out in parallel for an arbitrary number of LED branches. If all of the measurement resistors are not needed for setting the operating parameter, since the parameters are matched in the individual LED groups, then the measurement resistors of the additional LED branches can be used for other functions.

Alternatively, the other LED branches such as the second LED branch can be measured in the same manner as the first LED branch. To this end, a second measurement bridge for the second LED branch includes second measurement resistor 6 (which is connected in parallel to the second LED branch) and a series resistor 8. Resistor 8 is connected in series between an electronic switch 9 and ground. A second control circuit 13 can open and close switch 9. When switch 9 is closed while the second LED branch is blocked off (i.e., subject to a supply voltage less than the voltage required for LED 3 of the second LED branch to turn one and emit light), the second measurement bridge for the second LED branch comprising second measurement resistor 6 and resistor 8 is formed. Second control circuit 13 switches switch 9 closed during the measurement phase of the second LED branch. As such, control circuit 10 closes switch 9 during the measurement phase which takes place in the blocking region of LED 3. The result of the measurement is tapped from resistor 8 of the second measurement bridge and supplied to an evaluation circuit. In turn, the evaluation circuit changes the PWM for controlling LED 3 of the second LED branch as a function of the measurement value tapped from resistor 8 of the second measurement bridge. LED 3 of the second LED branch receives its operating current corresponding to the PWM by control circuit 13 simultaneously closing a switch 12 and opening switch 9. (Control circuit 13 opens switch 12 during the measurement phase and closes switch 12 when the operating current flows through LED 3 of the second LED branch.) As described, control circuit 13 and the evaluation circuit together include a clock pulse generator and a driver circuit for the clocked control of LED 3 of the second LED branch.

As such, control circuit 13 that controls second LED branch also has the same control behavior as control circuit 10. In addition, switch 7 indicated in the second LED branch which is parallel to the first LED branch is intended to illustrate that when a plurality of parallel measurement resistors are used, the measurement resistors can be switched on or off independently.

The measurement value in this measuring configuration represents the respective switch setting, whereby, for example, remote operating units with functional lighting can be achieved with a relatively small amount of cabling expenditure.

With reference to FIG. 2, which shows the operating states, the function of the control circuit is as follows. In LED operation, the supply voltage “Out” is raised to a voltage required by LEDs 3 for the LEDs to switch on and emit light. LEDs 3 are switched on by respective switches 12 switched closed. The brightness of LEDs 3 can be adjusted by the resulting pulse width modulation ratio (PWM-ratio). In order to measure measurement resistors 5, 6, the supply voltage of LEDs 3 is reduced below a value less than the forward voltage of the LEDs (the forward voltage being the voltage required for the LEDs to turn on and emit light). As such, during the measurement phase of measurement resistors 5, 6, LEDs 3 are blocked off. Each measurement resistor 5, 6 can be measured through a voltage divider of the corresponding measurement bridge by a respective switch 9 (which is now closed) and a respective switch 12 (which is now open). The use of only one voltage source, which is reversible and is a constant voltage source, is assured because none of LEDs 3 illuminate during the measurement even when the LEDs have different characteristics.

Thus, the unnecessary measurement resistors can be eliminated as only one measurement resistor of a single LED branch may be measured. However, this assumes that the protective resistors are matched so that a uniform brightness results for all LEDs, taking into consideration the different light intensities of the LEDs. The switching states of switch 7 can also be determined, or resistor values with high variance, such as temperature resistors with several 100 kOhm at low temperatures and 1 kOhm at high temperatures, can be provided in parallel circuits under switched control.

While embodiments of the present invention have been illustrated and described, it is not intended that these embodiments illustrate and describe all possible forms of the present invention. Rather, the words used in the specification are words of description rather than limitation, and it is understood that various changes may be made without departing from the spirit and scope of the present invention.

What is claimed is:

1. A control circuit comprising:
a clock pulse generator operable to output a pulse-frequency ratio to a constant voltage source in order to control the power output of the constant voltage source; and
a driver circuit for the clocked control of at least one light emitting diode (LED) to which a measurement resistor is connected in parallel, wherein the LED is supplied with power by the constant voltage source, wherein the LED is turned on when the power is greater than a forward power level and is turned off when the power is less than the forward power level;
wherein the driver circuit taps a measurement voltage of the measurement resistor while the LED is supplied with power less than the forward power level;
wherein the clock pulse generator varies the pulse-frequency ratio as a function of the measurement voltage of the measurement resistor.

2. The control circuit of claim 1 wherein:
the constant voltage source is reversible and the control circuit further including:
a series resistor connected in series with the measurement resistor, wherein the series resistor and the measurement resistor from a measurement bridge when the LED is turned off such that a voltage less than the forward power level of the LED can be applied by the constant voltage source and the measurement voltage can be tapped from the measurement bridge during the measurement period; and
an evaluation circuit operable to adjust the constant voltage source to a specific forward voltage and adjust the pulse-frequency ratio of the clock pulse generator as a function of the measurement voltage such that the light intensity of the LED is constant

3. The control circuit of claim 1 wherein:
a plurality of LEDs are connected in parallel in LED branches and only one LED branch has a measurement resistor connected in parallel to the LED branch.

4. The control circuit of claim 1 wherein:
the measurement resistor is at least one of a temperature-dependent resistor, an NTC-resistor, an adjustable resistor, and a light-sensitive resistor.

5. The control circuit of claim 2 wherein:
a plurality of LEDs are connected in parallel in LED branches with each LED branch having at least one LED connected in series;
wherein a measurement resistor is connected in parallel to each LED branch;
wherein the measurement voltage of one of the measurement resistors is provided to the evaluation circuit for the evaluation circuit to adjust the constant voltage source to the specific forward voltage and adjust the pulse-frequency ratio of the clock pulse generator such that the light intensity of the LEDs is constant.

6. The control circuit of claim 5 wherein:
the measurement resistors are individually connected in parallel to corresponding LED branches by respective switches.

7. The control circuit of claim 2 further comprising:
a switch in parallel to the series resistor for the pulsed conductive switching of the LED.

8. The control circuit of claim 1 wherein:
a protective resistor is connected in series with the LED.

9. The control circuit of claim 5 wherein:
the measurement resistors connected in parallel to the LEDs are matched.

10. The control circuit of claim 5 wherein:
each LED branch includes a protective resistor connected in series with the at least one LED of the LED branch.

11. The control circuit of claim 10 wherein:
the protective resistors are matched.

12. The control circuit of claim 1 wherein:
the LED is a component of a light on either a vehicle or a aircraft.

13. The control circuit of claim 1 wherein:
the LED is a component of a lamp.

14. A control system for a light emitting diode (LED) branch having at least one LED and a measurement resistor connected in parallel to the LED branch in which the LED branch is supplied with power by a constant voltage source such that the at least one LED is turned on when the power is greater than a forward power level and is turned off when the power is less than the forward power level, the control system comprising:
a control circuit operable for controlling the constant voltage source to supply power to the LED branch greater than the forward power level and less than the forward power level, the control circuit including a series resistor connectable in series with the measurement resistor to form a measurement bridge;
wherein the control circuit causes the series resistor to connect in series with the measurement resistor to form the measurement bridge while controlling the constant voltage source to supply power to the LED branch less than the forward power level such that the at least one LED of the LED branch is turned off, wherein the control circuit taps a measurement value of the measurement resistor while the measurement bridge is formed; and
an evaluation circuit operable to adjust the constant voltage source to a specific forward voltage and adjust a pulse-frequency ratio for the constant voltage source as a function of the measurement voltage such that the light intensity of the LED is constant.

15. The control system of claim 14 wherein a plurality of LEDs are connected in parallel in LED branches and only one LED branch has a measurement resistor connected in parallel to the LED branch.

16. The control system of claim 14 wherein:
the measurement resistor is at least one of a temperature-dependent resistor, an NTC-resistor, an adjustable resistor, and a light-sensitive resistor.

17. The control system of claim 14 wherein a plurality of LEDs are connected in parallel in LED branches with each LED branch having at least one LED connected in series and a measurement resistor is connected in parallel to each LED branch, wherein:
the measurement voltage of one of the measurement resistors is provided to the evaluation circuit for the evaluation circuit to adjust the constant voltage source to the specific forward voltage and adjust the pulse-frequency ratio for the constant voltage source such that the light intensity of the LEDs is constant.

18. The control system of claim 17 wherein the measurement resistors are individually connected in parallel to corresponding LED branches by respective switches.

19. The control system of claim 14 wherein:
the control circuit further includes a switch in parallel to the series resistor for the pulsed conductive switching of the LED.

20. The control system of claim 14 wherein a protective resistor is connected in series with the at least one LED.
